(19) United States
(12) Patent Application Publication
(10) Pub. No.: US 2001/0003062 A1
(43) Pub. Date: Jun. 7, 2001

(54) GATE SIDEWALL PASSIVATION TO PREVENT ABNORMAL TUNGSTEN POLYCIDE GROWTH

(76) Inventor: REBECCA Y. TANG, HSINCHU (TW)

Correspondence Address: GREGG GOLDMAN, PATENT DEPARTMENT, PROSKAUER ROSE, 1585 BROADWAY, NEW YORK, NY, 100368299

(21) Appl. No.: 09/184,869

(22) Filed: Nov. 3, 1998

(30) Foreign Application Priority Data
Aug. 20, 1998 (DE) 19837893.9

(51) Int. Cl. H01L 21/44

(52) U.S. Cl. 438/683

(57) ABSTRACT

A method for fabricating a semiconductor structure is provided. A WSiₓ (tungsten polycide) region is formed on an Si (silicon) region. At least a side surface of the WSiₓ region is covered with a Si liner. The Si liner is then oxidized to form an SiO₂ (silicon dioxide) liner covering the side surface of the WSiₓ region.

A semiconductor MOSFET is provided with a source, a drain, a channel region separating the source and drain and a gate. The gate includes a polycrystalline Si region, disposed over the channel region, and a WSiₓ gate region, disposed on the polycrystalline Si region. An oxidized SiO₂ liner is provided which covers at least a side surface of the WSiₓ gate region.

The Si liner stabilizes the WSiₓ region. That is, the Si liner reduces a stress in the WSiₓ region and reduces a production of WSiₓ extrusions from the WSiₓ region.

### FIELD OF THE INVENTION

The present invention pertains to semiconductor devices and their fabrication, such as MOSFET/IGFET devices and their fabrication.

### BACKGROUND OF THE INVENTION

This invention is illustrated herein in a DRAM MOSFET/IGFET application. However, those with ordinary skill in the art will appreciate the applicability of this invention to other transistor technologies and other classes of integrated circuit devices.

Specifically, there is a continuing trend to increase the storage capacity of semiconductor memory devices, such as DRAMs. This is achieved through a combination of new technologies that enable reduction of the dimensions of the components that make up the DRAM. Most notably, several innovations in device architecture and fabrication have been introduced to reduce the size of each storage cell of the memory array of a DRAM. Each storage cell is typically implemented as a MOSFET connected to a capacitor. The gate of the MOSFET is connected to a row conductor, e.g., a word line. The drain of the MOSFET is connected to a column conductor, e.g., a bit line. The source of the MOSFET is connected to a plate of the capacitor. The presence and absence of charge on the capacitor, respectively, correspond to different logic values stored by the storage cell. Through selective activation of (i.e., application of voltages to, or sensing of voltages from) the word and bit line of a particular storage cell, a particular logic value can be written in the storage cell, or the logic value stored in the storage cell can be read out.

As the dimensions of the MOSFET of the storage cell are reduced, the resistance of the gate of the MOSFET can increase to an undesirable level. The operating speed of the DRAM is a function of the gate resistance of the storage cell. Thus, it is desirable to reduce gate resistance.

FIGS. 1-2 illustrate a submicron fabrication process for forming a low resistance MOSFET gate from a polycide material. In FIG. 1, a gate oxide layer 12 is formed on a substrate by oxidation or deposition. A polycrystalline silicon or poly Si layer 14 is then deposited on the gate oxide layer 12. Next, a tungsten polycide or WSiₓ layer 16 is sputtered or deposited onto the poly Si layer 14. A capping nitride layer 18 is then formed on the WSiₓ layer 14. As shown in FIG. 2, the nitride layer 18, WSiₓ layer 16 and poly Si layer 14 are patterned to form gate regions 20. Illustratively, this is achieved using photolithographic and etching techniques.

A gate 20 that includes a WSiₓ region 16′ has a low gate resistance. However, such gates 20 also have drawbacks. For example, a conductor is typically formed adjacent to the gate 20 such as is shown in FIG. 3. As shown, a through-going metal via 22 fills a passage in a dielectric material 24, e.g., for purposes of forming an electrical connection to the source or drain of the MOSFET. The formation of the structure typically requires one or more high temperature (e.g., >750° C.) operations. Often, as a result of high temperature operations following the etching of the gate 20 from the layers 14, 16 and 18, extrusions form from the exposed sidewalls of the WSiₓ region 16′. These extrusions can short circuit the gate 20 to an adjacent (in the lateral direction) via 22. Even the processes used to form the nitride spacers 26 are not sufficient to prevent such extrusion to adjacent via short circuit failures. As a result, the conventional WSiₓ has an undesirable reduction in yield.

It is an object to overcome the disadvantages of the prior art.

### SUMMARY OF THE INVENTION

The invention achieves this and other objects. According to one embodiment, a method for fabricating a semiconductor structure is provided. A WSiₓ region is formed on an Si region, such as a poly Si region. At least a side surface of the WSiₓ region is covered with a Si liner. The Si liner is then oxidized to form an SiO₂ liner covering the side surface of the WSiₓ region.

According to another embodiment, a semiconductor MOSFET is provided with a source, a drain, a channel separating the source and drain, and a gate. The gate includes a poly Si region, disposed over the channel region, and a WSiₓ gate region, disposed on the poly Si region. An oxidized SiO₂ liner is provided which covers at least a side surface of the WSiₓ gate region.

The Si liner stabilizes the WSiₓ region. That is, the Si liner: (1) tends to prevent the WSiₓ region from oxidizing, and (2) tend to reduce a stress in the WSiₓ region. These results are achieved because an abundant amount of Si is provided by the Si liner wrapped around the stacked gate regions including the WSiₓ region.

### BRIEF DESCRIPTION OF THE DRAWING

FIGS. 1-2 show a conventional WSiₓ gate formation process.

FIG. 3 shows a conventional semiconductor structure including a WSiₓ gate and laterally adjacent via.

FIGS. 4-7 show a process for forming a semiconductor structure including a WSiₓ gate according to a first embodiment of the invention.

FIGS. 8-10 show a process for forming a semiconductor structure including a WSiₓ gate according to a second embodiment of the invention.

FIG. 11 shows a semiconductor structure including a WSiₓ gate and laterally adjacent via according to a first embodiment of the present invention.

FIG. 12 shows a semiconductor structure including a WSiₓ gate and laterally adjacent via according to a second embodiment of the present invention.

### DETAILED DESCRIPTION OF THE INVENTION

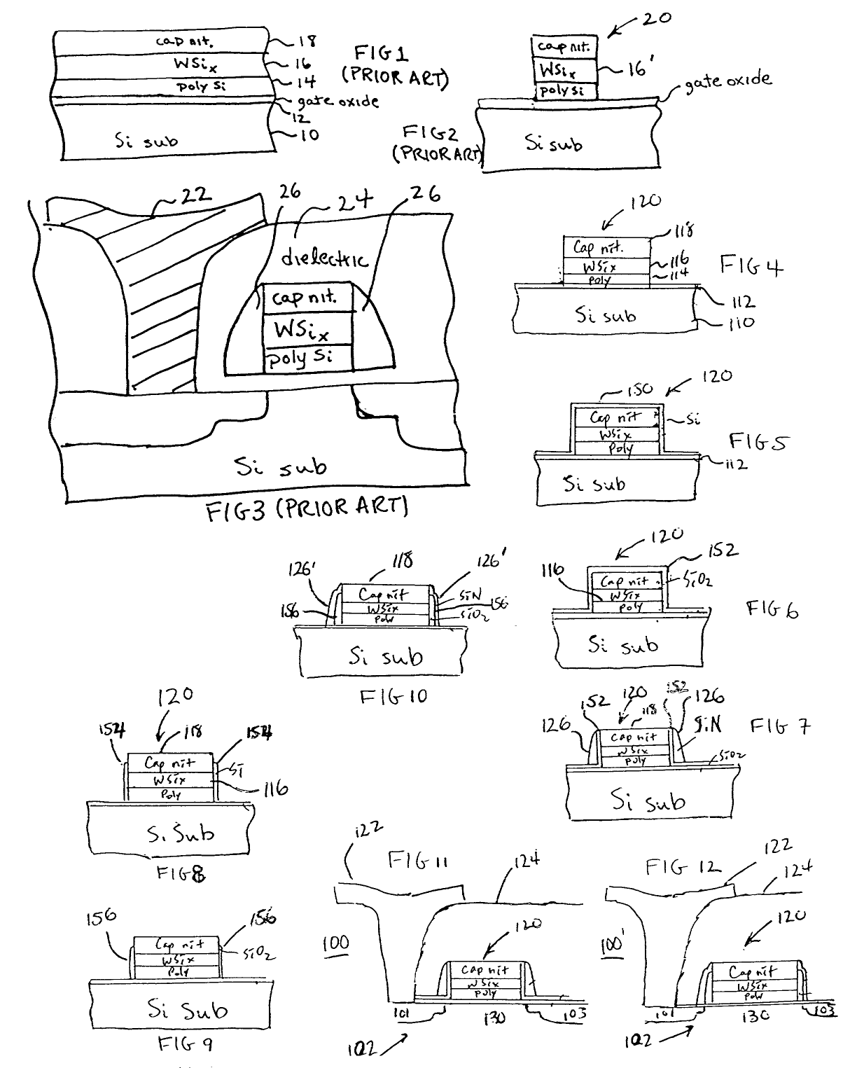

The invention is illustrated below in a sub-half μm fabrication process for forming a MOS device of a storage cell in a 64 Mbit DRAM, although the invention is applicable to other MOS and non-MOS technologies, memory and non-memory integrated circuits and other devices of memory integrated circuits. The fabrication process according to the invention may incorporate certain conventional steps such as shown in FIGS. 1-2 and described above. FIG. 4 shows a cross-section of the semiconductor wafer in the vicinity of a MOSFET at an interim fabrication step. Illustratively, the gate oxide 112 formed (by deposition or oxidation) on the substrate 110 illustratively is SiO₂ and has a thickness in the range of about 50 to 120 Å. The poly Si region 114 is patterned from a poly Si layer deposited on the gate oxide 112 to a thickness in the range of about 800 to 1,500 Å. The WSiₓ region 116 is patterned from a WSiₓ layer sputtered or deposited onto the poly Si layer to a thickness in the range of about 600 to 1,000 Å. The cap nitride region 118 is patterned from a nitride layer containing SiN and which is deposited on the WSiₓ layer to a thickness in the range of about 1,500 to 2,500 Å. The cap nitride region 118, WSiₓ region 116 and thick poly Si region 114 collectively form a gate region 120. The gate region illustratively has a lateral width of about 0.3 μm. This width is advantageously made as small as possible considering the photo-lithographic resolution of the patterning process used to etch the regions 114, 116 and 118 of the gate 120. As described above, the gate 120 illustratively is formed by vertically etching through the nitride, WSiₓ and the thick poly Si layers.

Next, as shown in FIG. 5, a thin Si liner layer 150 is deposited on the top and side surfaces of the gate 120 and top surfaces of the gate oxide 112 not covered by the gate 120. The thin Si liner layer 150 may be formed in a precisely controlled manner by deposition in a chemical vapor deposition (CVD) chamber (e.g., an Applied Materials™ HTF type poly or WSiₓ chamber or its equivalent). Illustratively, in the deposition process, an SiH₄ gas is introduced at a temperature in the range of about 500° C. to 600° C., at a pressure of about 0.5 to 5 Torr, and for a time of about 60 to 120 seconds. This forms a thin Si liner layer 150 having a thickness in the range of about 50 Å to 150 Å.

The Si liner layer 150 contacts all exposed (lateral) side surfaces of the WSiₓ region 116. This tends to stabilize the WSiₓ region 116. That is, this tends to prevent the WSiₓ region 116 from oxidizing and tends to relieve a stress in the WSiₓ region 116. Such results occur by virtue of providing an abundant amount of Si in the thin Si liner layer 150 which wraps around the gate 120 stack. That is, absent the Si liner layer 150, the WSiₓ region 116 is known to change phase when exposed to a temperature of 750° C. or higher. Such a phenomenon can result in the undesired production of conductive WSiₓ extrusions, which extrusions can electrically connect the gate 120 to an adjacent conductor (such as a conductive via). The Si liner layer 150 provides a source of Si for reacting with the WSiₓ region 116. In this fashion the Si liner layer 150 retards such abnormal reactions that produce the extrusions. This, in turn, dramatically reduces the likelihood of the WSiₓ extrusion to adjacent conductor short circuit failure.

Next, as shown in FIG. 6, the Si liner layer 150 is oxidized to produce an SiO₂ layer 152 in a rapid thermal oxidation (RTO) process. Illustratively, this is achieved by heating the wafer in the presence of oxygen at a temperature in the range of about 950° C. to 1,100° C. and for a period of time in the range of about 80 seconds to 100 seconds. This forms an SiO₂ liner layer 152 having a thickness in the range of about 100 Å to 200 Å. Thus, as an added benefit, the Si material of the Si liner layer 150 that does not react with the WSiₓ region 116 is oxidized to increase the lateral thickness of the spacers formed laterally adjacent to the gate 120.

As shown in FIG. 7, nitride spacers 126, for example, including SiN, are formed laterally adjacent to the lateral side surfaces of the SiO₂ liner layer 152. In the embodiment shown in FIG. 7, the SiO₂ liner layer 152 covers all (previously) exposed surfaces of the gate 120 including each side and top surface of the cap nitride region 118. Thus, the spacers 126 do not contact the cap nitride region 118; rather the SiO₂ liner layer 152 isolates the cap nitride region 118 from the nitride spacers 126. Illustratively, the nitride spacers 126 are formed using any well known process, such as depositing a nitride layer on the entire top surface of the wafer and anisotropicaly etching back the nitride layer to form the side spacers 126. (The anisotropic etch removes the SiO₂ material of the liner 152 from the top of the gate 120.) The width of the spacers 126 can be in the range of about 400 Å to 500 Å. The spacer 126 width is a function of the height of the gate 120.

FIGS. 8-10 illustrate a variation of the process noted above. Referring to FIG. 8, after forming the Si liner layer 150 (FIG. 5), the wafer is subjected to a vertical etch. For example, an anisotropic etch with HBr/HCl/Cl₂ chemistry may be performed. A HBr, HCl or Cl₂ chemistry etchant has a high etch selectivity to oxide and provides good control for etching the Si liner layer 150. Such a process may be carried out in a TCP 9600™ chamber with the wall and electrode temperature set to about 50° C., a power of about 200 to 300 Watts and the pressure set to about 5 to 10 mTorr (or equivalent settings in other types of chambers). This produces Si liner spacers 154 on the lateral side surfaces of the gate 120. The Si liner spacers 154 illustratively entirely cover the lateral side surfaces of the WSiₓ region 116, to provide as much contact between Si material of the Si liner spacers 154 and the WSiₓ region 116 as possible. However, the Si liner spacers 154 illustratively cover less than all of the side surfaces of the cap nitride region 118 and do not cover the top surface of the cap nitride region 118.

Next, as shown in FIG. 9, the Si liner spacers 154 are oxidized. A similar process as described in connection with FIG. 6 may be used. This produces SiO₂ liner spacers 156. The SiO₂ liner spacers 156 illustratively have a width in the range of about 100 Å to 200 Å.

As shown in FIG 10, nitride spacers 126′ are formed adjacent to, and contacting, the SiO₂ liner spacers 156. The nitride spacers 126′ differ from the nitride spacers 126 of FIG. 7 in that the nitride spacers 126′ contact at least a portion of the side surface of the cap nitride 118 not already covered by the SiO₂ liner spacers 156. As a result, the nitride spacers 126′ have a different shape than the nitride spacers 126 (FIG. 7) and a width in the range of about 400 Å to 500 Å. A similar process may be used to form the nitride spacers 126′ as is used to form the nitride spacers 126.

FIGS. 11 and 12 illustrate a structure 100 or 100′ incorporating a WSiₓ region 116 that is stabilized using an Si liner according to the invention. In particular, the structure 100 is formed using the process illustrated in FIGS. 4-7 and the structure 100′ is formed using the process illustrated in FIGS. 4, 5 and 8-10. Illustratively, each structure 100 or 100′ is a MOSFET 102 with laterally adjacent conducting (e.g., metallic) via 122 formed in a passage through a covering dielectric 124. The formation of the sources 101 and drains 103 of the MOSFETs 100 and 100′, the dielectric layer 124 and the via 122 are not described. However, any combination of conventional processes can be used, most notably, those involving high temperatures that are equal to or exceed 750° C. In both the structure 100 and the structure 100′, the gate 120 is formed over a channel region 130 separating the source 101 from the drain 103. Note that the via 122 may be on the other lateral side of the gate 120, i.e., connected to the drain 103 or some other region. Alternatively, the conductor adjacent to the gate 120 need not be a via.

The above discussion is intended to be merely illustrative of the invention. Those having ordinary skill in the art may devise numerous alternative embodiments without departing from the spirit and scope of the following claims.

The claimed invention is:

1. A method for fabricating a semiconductor structure comprising:
(a) forming a WSiₓ region on an Si region,
(b) covering at least a side surface of said WSiₓ region with a Si liner, and
(c) oxidizing said Si liner to form an SiO₂ liner covering said side surface of said WSiₓ region.

2. The method of claim 1 wherein said Si liner reduces production of WSiₓ protrusions from said WSiₓ region at high temperatures.

3. The method of claim 1 wherein said step (a) further comprises the step of sputtering said WSiₓ region onto said Si region.

4. The method of claim 1 wherein said step (a) further comprises the step of depositing said WSiₓ region onto said Si region.

5. The method of claim 1 further comprising the steps of:
forming a gate oxide layer on a Si substrate,
forming said Si region on said gate oxide layer, and
forming a nitride region on said WSiₓ region.

6. The method of claim 1 further comprising the step of:
forming a conducting region adjacent to said SiO₂ liner, said Si material of said SiO₂ liner preventing a short circuit extrusion from forming between said WSiₓ region and said conducting region.

7. The method of claim 6 wherein said conducting region is a conducting via.

8. The method of claim 1 further comprising the step of:
(d) forming a cap region on a top surface of said WSiₓ region,
wherein said step (b) further comprises the steps of covering each exposed side surface of said WSiₓ region and said top and side surfaces of said cap region with said Si liner.

9. The method of claim 8 further comprising the steps of:
(b1) prior to step (c), vertically etching back said Si liner, and
(e) after step (c), forming a spacer adjacent to at least one side wall of said SiO₂ liner.

10. The method of claim 8 further comprising the step of:
(e) after step (c), forming a spacer adjacent to at least one side wall of said SiO₂ liner.

11. A semiconductor MOSFET comprising:
(a) a source,
(b) a drain,
(c) a gate including, a polycrystalline Si region, disposed over a channel region separating said source and drain regions, and a WSiₓ gate region, disposed on said polycrystalline Si region, and
(d) an oxidized SiO₂ liner covering at least a side surface of said WSiₓ gate region.

12. The semiconductor MOSFET of claim 11 wherein said gate further comprises:
(e) a gate oxide layer disposed on said channel region and below said polycrystalline Si region, and
(f) a nitride region disposed on said WSiₓ gate region.

13. The semiconductor MOSFET of claim 12 further comprising:
(g) a nitride spacer formed adjacent to a first side surface of said oxidized SiO₂ liner, which first side surface is opposite a second side surface of said oxidized SiO₂ layer that is adjacent to said side surface of said WSiₓ gate region covered by said oxidized SiO₂ liner.

14. The semiconductor MOSFET of claim 13 wherein said oxidized SiO₂ liner contacts at least a side surface of said nitride region and wherein said nitride spacer is isolated from said side surface of said nitride region by said oxidized SiO₂ liner.

15. The semiconductor MOSFET of claim 13 wherein said oxidized SiO₂ liner covers less than all of a side surface of said nitride region, said nitride spacer contacting at least a part of said side surface of said nitride region not covered by said oxidized SiO₂ liner.

16. The semiconductor MOSFET of claim 11 wherein said oxidized SiO₂ liner is formed from an oxidization of an Si liner deposited on said WSiₓ gate region.
